(19) United States
(12) Patent Application Publication
(10) Pub. No.: US 2002/0164836 A1
(43) Pub. Date: Nov. 7, 2002

(54) Method of manufacturing printed circuit board

(75) Inventor: Sheng-Chun Ho, Kaohsiung (TW)

Correspondence Address: LOWE HAUPTMAN GILMAN & BERNER, LLP, 1700 Diagonal Road, Suite 310, Alexandria, VA, 22314, US

(73) Assignee: ADVANCED SEMICONDUCTOR ENGINEERING INC.

(21) Appl. No.: 09/849,247

(22) Filed: May 7, 2001

(51) Int. Cl. H01L 21/44; H01L 21/48; H01L 21/4763

(52) U.S. Cl. 438/106; 438/127; 438/725; 438/637

(57) ABSTRACT

A method of manufacturing a printed circuit board comprising the steps of: providing a substrate in which conductor circuits have been formed; forming a solder resist layer on the surface of the substrate; pre-curing the solder resist; imaging and developing the solder resist layer so as to form a desired solder resist pattern wherein a solder resist scum is remained on the substrate; post-curing the solder resist; and removing the solder resist scum. The solder resist scum removing step may be conducted by a permanganate desmearing process, a dichromate desmearing process, a plasma desmearing process, or a sand blasting process. The present invention further provides a method of improving the adhesion between a molding compound and a circuitized substrate with a solder resist layer formed thereon. The adhesion improving method mainly comprises roughening the solder resist layer on the circuitized substrate by a permanganate desmearing process, a dichromate desmearing process, a plasma desmearing process, a sand blasting process, or by a scrubbing process.

### BACKGROUND OF THE INVENTION

1. Field of the Invention

The present invention generally relates to a method of manufacturing a printed circuit board. Furthermore, the present invention is concerned with a circuitized substrate for use in forming an electronic package, and more particularly to a method of improving the adhesion between a molding compound and a circuitized substrate with a solder resist layer formed thereon.

2. Description of the Related Art

Usually, printed circuit boards are formed from a layer of conductive material (commonly, copper or copper plated with solder or gold) carried on a substrate of insulating material (commonly glass-fiber-reinforced epoxy resin). A printed circuit board having two conductive surfaces positioned on opposite sides of a single insulating layer is known as a “double-sided circuit board.” To accommodate even more circuits on a single board, several copper layers are sandwiched between layers of insulating material to produce a multilayer circuit board.

Conventional process for use in making a printed circuit board comprises the steps of:

(a) laminating a conductive metal layer on both sides of a dielectric layer (suitable dielectric material such as fiberglass reinforced BT (bismaleimide-triazine) resin or FR-4 fiberglass reinforced epoxy resin) by conventional methods such as thermocompression; (b) forming vias and through-holes in the product of step (a) by any of a number of well-known techniques such as mechanical drilling or laser drilling, and then electroless plating the vias and through-holes with a layer of electrically conductive metal such as copper; (c) forming desired conductive traces from the conductive metal layer on both sides of the substrate by photolithography and etching; (d) forming a photoimagable solder resist over the patterned surfaces of the substrate, transferred a predetermined pattern, and then developed to form a desired solder resist pattern; and (e) plating a material which allows a good bond to be formed with conventional material of bonding wires such as gold or palladium on exposed portions of the conductive traces.

During the step (b), the act of drilling leaves a smear of insulating material in the barrel of the hole. This smear cause reliability problems and must be removed prior to proceeding the electroless plating step. Smear removal processes and solvents are known in the art. Several mechanical and chemical desmear methods that are known in the art are described in U.S. Pat. No. 4,601,783, issued Jul. 22, 1986 to Krulik. U.S. Pat. No. 4,820,548 to Courduvelis et al. describes a desmear process utilizes an alkaline permanganate solution to remove the resin smear.

Typically, a surface treatment process, e.g. roughening process is introduced before proceeding the step (d) for enhancing surface roughness of the conductive traces so as to promote adhesion between the solder resist and the conductive traces. However, this also results in the problem that, after developing the solder resist during step (d), some solder resist scum still remain on the conductive traces. This solder resist scum also cause reliability problems and must be removed prior to proceeding the step (e).

Conventionally, an electronic package includes a circuitized substrate (usually, a printed circuit board) with one or more active devices attached thereon; packages including only one device are known as Single Chip Modules (SCM), while packages including a plurality of devices are called Multi Chip Modules (MCM). The active device is typically a semiconductor chip commonly made of Silicon, Germanium or Gallium Arsenide. Typically, the electronic package has a package body to provide environmental sealing and electrical insulation for the semiconductor chip. The package body is formed over the semiconductor chip using known plastic molding methods such as transfer molding. Usually, this is accomplished by placing the circuitized substrate with semiconductor chip in a mold having cavities and thereafter pouring molding compound to fill the mold cavities.

However, since the interface between the package body and the solder resist on the circuitized substrate is quite flat, bonding mechanism between the package body and the solder resist involves only chemical bonding but not mechanic interlock. Therefore, when the conventional electronic package is subjected to high temperature/pressure/humidity environment such as pressure cook test (PCT), the interface between the package body and the solder resist is easily attacked by water and then debonds to form delamination between the package body and the solder resist in macroscopic view.

### SUMMARY OF THE INVENTION

It is therefore an object of the present invention to provide a method of improving the adhesion between the molding compound and the circuitized substrate with a solder resist layer formed thereon which overcomes, or at least reduces the above-mentioned problems of the prior arts

It is another objective of the present invention to provide a method of manufacturing a printed circuit board which further comprises a de-scum process proceeded after forming the solder-resist thereby overcoming, or at least reducing the above-mentioned problems of the prior arts.

Accordingly, in a first aspect, the present invention provides a method of improving the adhesion between a molding compound and a circuitized substrate with a solder resist layer formed thereon. The method mainly comprises roughening the solder resist layer on the circuitized substrate by a permanganate desmearing process. The permanganate desmearing process involves three different solution treatments including a solvent swell solution (such as diethylene glycol monobutyl ether), a alkaline permanganate solution, and a neutralization solution (such as inorganic acidic solutions), used sequentially. Alternatively, the alkaline permanganate solution may be replaced by an alkaline dichromate solution. In other preferred embodiments of the present invention, the surface roughing step may be accomplished by a plasma desmearing process, a sand blasting process, or by a scrubbing process.

Since the solder resist layer on the circuitized substrate has a rough surface after subjecting to a surface roughing treatment, bonding mechanism between the package body and the solder resist includes chemical bonding as well as mechanic interlock. Mechanic interlock has solvent-resist feature; hence, the electronic package formed from the circuitized substrate of the present invention has much better reliability under high temperature/pressure/humidity environment such as pressure cook test (PCT).

According to a second aspect, this invention further provides a method of manufacturing a printed circuit board comprising the steps of: (a) providing a substrate in which conductor circuits have been formed; (b) forming a solder resist layer on the surface of the substrate; (c) pre-curing the solder resist; (d) imaging and developing the solder resist layer so as to form a desired solder resist pattern wherein a solder resist scum is remained on the substrate; (e) post-curing the solder resist; and (f) removing the solder resist scum.

In the preferred embodiments of the present invention, the solder resist scum removing step may be conducted by a permanganate desmearing process, a dichromate desmearing process, a plasma desmearing process, or a sand blasting process.

### BRIEF DESCRIPTION OF THE DRAWINGS

Other objects, advantages, and novel features of the invention will become more apparent from the following detailed description when taken in conjunction with the accompanying drawings.

FIGS. 1-6 illustrate a method of manufacturing a printed circuit board in accordance with a preferred embodiment of the present invention.

### DETAILED DESCRIPTION OF THE PREFERRED EMBODIMENT

The circuitized substrate for use with the present invention may be formed from a core layer made of fiberglass reinforced BT (bismaleimide-triazine) resin or FR-4 fiberglass reinforced epoxy resin. The circuitized substrate may be formed by the following step of: (a) laminating a conductive metal layer such as a copper foil with a roughed surface on both sides of a core layer by conventional methods such as thermocompression; and (b) forming desired conductive traces or conductive regions from the copper foil on both sides of the core layer by photolithography and etching. It could be understood that the circuitized substrate for use with the present invention may include any number of layers of conductor circuits if desired.

The circuitized substrate for use with the present invention is already provided with a solder resist layer on the patterned surfaces thereof. The solder resist layer may be formed by the following step of: (a) forming a solder resist such as photoimagable solder resist or dry film solder resist over the patterned surfaces of the substrate by a dipping method, spray method, screen printing, and so on; (b) conducting a precuring step in which the solder resist layer is heated at a temperature of 60° C. to 100° C. to obtain a solder resist film; and (c) imaging and developing the solder resist layer so as to form a desired solder resist pattern in which, as is well-known, a photomask is used to image only certain area of the solder resist film which, when developed, are removed to leave predetermined portions of the substrate exposed.

According to one aspect of the present invention, the method of improving the adhesion between a molding compound and a circuitized substrate with a solder resist layer formed thereon mainly comprises roughening the solder resist layer on the circuitized substrate by a permanganate desmearing process that involves three chemical steps. In the first step, a solvent swell solution (such as diethylene glycol monobutyl ether) is applied to attack and soften the structure of the solder resist; in the second step, a permanganate oxidizer (such as alkaline solutions of sodium, potassium or lithium permanganate) is applied to roughen the surface of the solder resist layer on the substrate; in the third step, a neutralizer, e.g., inorganic acidic solutions such as dilute sulfuric acid or hydrochloric acid, is applied to neutralize and remove the permanganate from the surface of the substrate. Typically, a to-be-treated circuitized substrate is dipped or otherwise exposed to each solution, with a deionized water rinse between each of the three treatment solutions. Specifically, in the second step, the alkaline permanganate solution is heated up to 160° F. or higher, and the dwell time is at least 20 minutes. Alternatively, the alkaline permanganate solution may be replaced by an alkaline dichromate solution.

In other preferred embodiments of the present invention, the surface roughing step may be accomplished by a plasma desmearing process, a sand blasting process, or by a scrubbing process.

In the plasma desmearing process, the circuitized substrate with a solder resist layer thereon is placed between a pair of parallel plasma plates which are separated from one another and which extend over the entire surface area of the substrate. Typically, the plasma desmearing process is accomplished within an airtight chamber in which the air is evacuated by a pump and replaced with a known mixture of selected gases such as oxygen and freon. Then, a high power radio frequency electric field is applied to the plates to generate a plasma between the plates. The plasma around the to-be-treated substrate between the two plates produces a plurality of discharge sparks that roughens the surface of the solder resist layer on the circuitized substrate.

During the sand blasting process, pressurized water is often used as a propellant. Usually, water type sand blasting generally allows more rapid and efficient surface abrasion, or cleaning, than air type sand blasting.

In the scrubbing process, the circuitized substrate with a solder resist layer thereon is surface-treated by jet-scrub polishing with the use of an abrasive, washing with water and drying; alternatively, the substrate may be polished with the use of a roll buff, washed with water and then dried.

In a first aspect, applicant's invention provides a surface roughing method by applying technologies of desmearing process. Since the solder resist layer on the circuitized substrate has a rough surface after subjecting to a surface roughing treatment, bonding mechanism between the package body and the solder resist includes chemical bonding as well as mechanic interlock. Mechanic interlock has solvent-resist feature; hence, the electronic package formed from the circuitized substrate of the present invention has much better reliability under high temperature/pressure/humidity environment such as pressure cook test (PCT).

According to a second aspect, this invention further provides a method of manufacturing a printed circuit board. The present invention will be hereinafter described the method in details on the basis of the embodiment shown in the drawings.

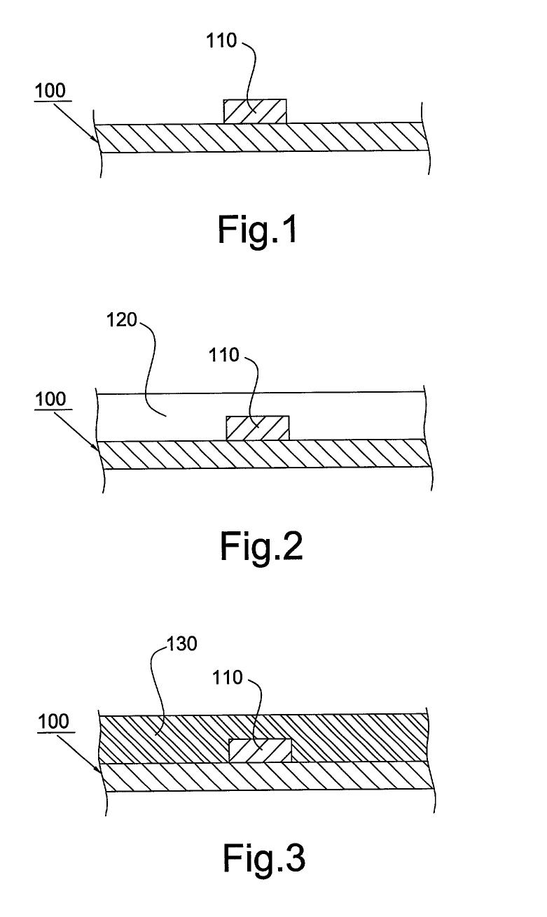

FIG. 1 shows a substrate 100 in which conductor circuits have been formed. Though only one layer of conductor circuit of the substrate 100 is shown in FIG. 1, the substrate 100 for use with the invention can include any number of layers of conductor circuits if desired. The substrate 100 may be formed from a core layer made of fiberglass reinforced BT or FR-4 resin. The substrate may be formed by the following step of: (a) laminating a conductive metal layer such as a copper foil with a roughed surface on both sides of a core layer by conventional methods such as thermocompression; and (b) forming desired conductive traces, e.g., trace 110 shown in FIG. 1, from the copper foil on both sides of the core layer by photolithography and etching.

Referring to FIG. 2, a solder resist 120 is applied over the patterned surfaces of the substrate 100 by a dipping method, spray method, screen printing, and so on. Then, a precuring step is conducted in which the solder resist layer is heated at a temperature of 60° C. to 100° C. to obtain a solder resist film 130 (see FIG. 3).

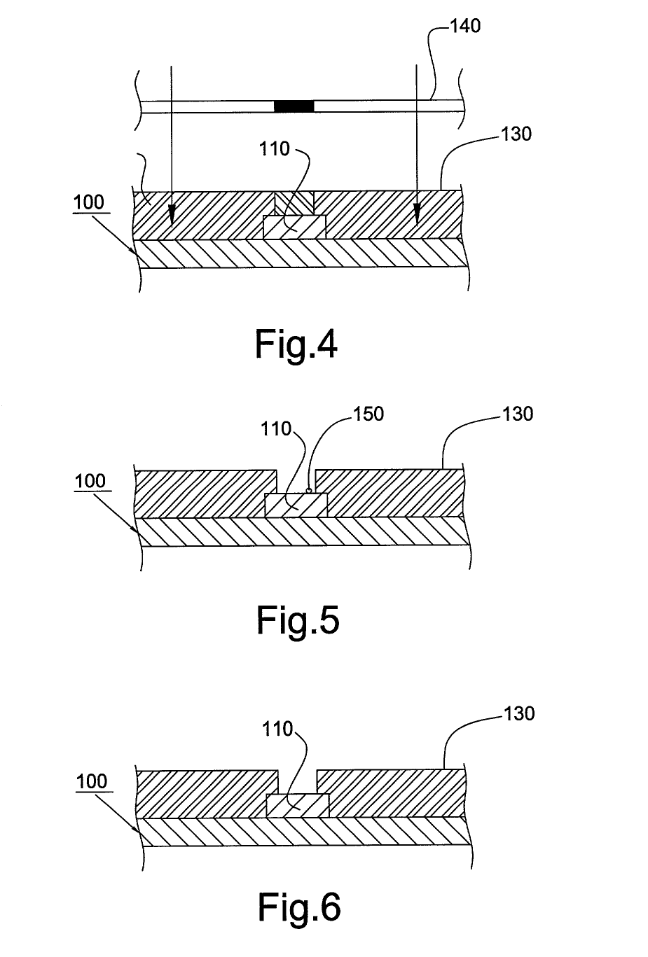

Referring to FIG. 4 and FIG. 5, the solder resist film 130 is imaged and developed so as to obtain a desired solder resist pattern. As shown, a photomask 140 having a desired pattern is used to image only certain areas of the solder resist film which, when developed, are removed to leave predetermined portions of the trace 110 exposed. Specifically, ultraviolet is radiated to the solder resist film through the mask 140 by using a light source such as a high-pressure mercury-vapor lamp, xenon lamp, or chemical lamp. After the ultraviolet radiation, unexposed portions of the solder resist film are dissolved by an alkaline solution to obtain a patterned solder resist film. Then, the patterned resist ink film is heated at 120° C. to 180° C. for about 30 minutes to cure the epoxy compound in the solder resist film, so that strength, hardness and chemical resistance of the resist ink film are improved. This step is known as a post-curing step.

However, as shown in FIG. 5, when the solder resist film 130 is developed, some scum 150 still remain on the conductive trace 110 of the substrate. Therefore, the present invention further provides a de-scum process for removing the solder resist scum remained on the substrate.

In the preferred embodiments of the present invention, the solder resist scum removing step may be conducted by a permanganate desmearing process, a dichromate desmearing process, a plasma desmearing process, or a sand blasting process. Details of each process are substantially the same as those described above.

In a second aspect, applicant's invention consists of applying technologies of known desmearing process as a de-scum process to remove the solder resist scum remained on the conductor traces of the substrate thereby assuring the reliability of following plating process.

Although the invention has been explained in relation to its preferred embodiment, it is to be understood that many other possible modifications and variations can be made without departing from the spirit and scope of the invention as hereinafter claimed.

What is claimed is:

1. A method of improving the adhesion between a molding compound and a circuitized substrate with a solder resist layer formed thereon, the circuitized substrate being adapted for packaging a semiconductor device, the semiconductor device being encapsulated against the substrate in the molding compound, the method comprises roughening the solder resist layer formed on the circuitized substrate.

2. The method as claimed in claim 1, wherein the step of roughening the solder resist layer is conducted by a permanganate desmearing process.

3. The method as claimed in claim 2, wherein the permanganate desmearing process involves three different solution treatments including a solvent swell solution, a alkaline permanganate solution, and a neutralization solution, used sequentially.

4. The method as claimed in claim 3, wherein the solvent swell solution comprises a diethylene glycol monobutyl ether.

5. The method as claimed in claim 3, wherein the neutralization solution comprises inorganic acidic solutions.

6. The method as claimed in claim 1, wherein the step of roughening the solder resist layer is conducted by a dichromate desmearing process.

7. The method as claimed in claim 6, wherein the dichromate desmearing process involve three different solution treatments including a solvent swell solution, an alkaline dichromate solution, and a neutralization solution, used sequentially.

8. The method as claimed in claim 7, wherein the solvent swell solution comprises a diethylene glycol monobutyl ether.

9. The method as claimed in claim 7, wherein the neutralization solution comprises inorganic acidic solutions.

10. The method as claimed in claim 1, wherein the step of roughening the solder resist layer is conducted by a plasma desmearing process.

11. The method as claimed in claim 1, wherein the step of roughening the solder resist layer is conducted by a sand blasting process.

12. The method as claimed in claim 1, wherein the step of roughening the solder resist layer is conducted by a scrubbing process.

13. A method of manufacturing a printed circuit board comprising the steps of:
providing a substrate in which conductor circuits have been formed;
forming a solder resist layer on the surface of the substrate;
pre-curing the solder resist;
imaging and developing the solder resist layer so as to form a desired solder resist pattern wherein a solder resist scum is remained on the substrate;
post-curing the solder resist; and
removing the solder resist scum.

14. The method as claimed in claim 13, wherein the step of removing the solder resist scum is conducted by a permanganate desmearing process.

15. The method as claimed in claim 14, wherein the permanganate desmearing process involves three different solution treatments including a solvent swell solution, a alkaline permanganate solution, and a neutralization solution, used sequentially.

16. The method as claimed in claim 15, wherein the solvent swell solution comprises a diethylene glycol monobutyl ether.

17. The method as claimed in claim 15, wherein the neutralization solution comprises inorganic acidic solutions.

18. The method as claimed in claim 13, wherein the step of removing the solder resist scum is conducted by a dichromate desmearing process.

19. The method as claimed in claim 18, wherein the dichromate desmearing process involve three different solution treatments including a solvent swell solution, an alkaline dichromate solution, and a neutralization solution, used sequentially.

20. The method as claimed in claim 19, wherein the solvent swell solution comprises a diethylene glycol monobutyl ether.

21. The method as claimed in claim 19, wherein the neutralization solution comprises inorganic acidic solutions.

22. The method as claimed in claim 13, wherein the step of removing the solder resist scum is conducted by a plasma desmearing process.

23. The method as claimed in claim 13, wherein the step of removing the solder resist scum is conducted by a sand blasting process.
